(19) United States
(12) Patent Application Publication
(10) Pub. No.: US 2007/0124915 A1
(43) Pub. Date: Jun. 7, 2007

(54) Manufacture of toroidal transformers

(75) Inventors: Jorgen Ekelof, Molndal (SE); Allan Ericsson, Helsinborg (SE)

Correspondence Address: HARNESS, DICKEY & PIERCE, P.L.C., P.O. BOX 8910, RESTON, VA, 20195, US

(73) Assignee: PANPOWER AB, Helsingborg (SE)

(21) Appl. No.: 10/562,030

(22) PCT Filed: Jun. 23, 2004
(86) PCT No.: PCT/SE04/01007

§ 371 Date: Dec. 21, 2006

(30) Foreign Application Priority Data
Jul. 4, 2003 (SE) 0301973-4

(51) Int. Cl. H01F 7/06; G11C 5/12

(52) U.S. Cl. 29/602.1; 29/737; 29/606

(57) ABSTRACT

The present invention relates to a novel and efficient method for manufacture of toroidal transformers, a bobbin for manufacture of toroidal transformers and a system for performing said method for manufacture of toroidal transformers. Said method for manufacture of toroidal transformers has properties superior for automated mass production and comprises the steps of arranging a coil around the periphery of at least one hollow bobbin of elongated shape and of flexible material; bending said at least one bobbin, together with said coil, so that the bobbin ends are brought towards each other, one of said bobbin ends defining an opening; and feeding a ribbon of magnetic material through said opening, so that said ribbon is being wound a required amount of tightly packed winding turns inside said bobbin until essentially the whole interior cavity of said bobbin is filled, said ribbon thereby forming a core.

### TECHNICAL FIELD OF THE INVENTION

The present invention relates to toroidal transformers and more specifically to a novel and efficient method for manufacture of toroidal transformers, a bobbin for manufacture of toroidal transformers and a system for performing said method for manufacture of toroidal transformers.

### BACKGROUND ART

Many suggestions have been made to provide a toroidal transformer having a wound, circular shaped core and windings surrounding the core. The lion's share of prior art suggestions comprises a winding process in which the coil is wound on a continuous toroidal-shaped core using conventional winding machines. Most commonly the coil is repeatedly threaded through the empty center hole in the transformer. There is also method using a slave roller as shown, for example, in U.S. Pat. No. 4,771,957.

Alternatively, some suggestions have been made on how to feed a continuous or nearly continuous core material into preformed windings. One early example of such an effort is shown in U.S. Pat. No. 2,191,393. Other exampels are provided in U.S. Pat. No. 6,145,774, 4,765,861, and 4,896,839.

In U.S. Pat. No. 4,779,812, the high voltage winding is wound into a number of wedge-shaped bundles, which then are arranged into two preformed, semi-circular transformer sections, each corresponding to about one-half of the transformer. Each wedge-shaped segment is wound and formed from a continuous wire, but only between 30 to 50 percent of the total length of voltage coil is allowed to be wound from a continuous wire. A single, continuous, ribbon-like strip, or a number of strips in parallel arrangement, is then fed through a gap between adjacent ends of the semi-circular sections and wound in place into an arcuate elongated passage formed in said sections to form a magnetic core. Belt means, engaging the radially-outward winding of said magnetic core as it is being wound within said arcuate elongated passage, is used to facilitate the winding of said core.

The device shown in U.S. Pat. No. 4,779,812 is mainly intended for manufacture of larger toroids that are not applicable in small electrical equipment, such as adaptors. Furthermore, the individual winding of the many wedge-shaped bundles and arranging them so that said arcuate elongated passage is formed, and the subsequent feeding of the ribbon into said passage is a cumbersome, relatively labour-intensive and time-consuming process, not suitable for automated mass production of small transformers up to 50 VA.

Evidently, there is a need for a method with which it is possible to effectively manufacture toroidal transformers at lower production costs, especially adapted for automated mass-production of small transformers up to 50 VA that are suitable for use in electrical equipment, such as adaptors.

### GENERAL DISCLOSURE OF THE INVENTION

The key object of the present invention is to mitigate limitations related to the types described above.

An object of the present invention is to provide a method and a system for manufacture of small toroidal transformers, primarily up to 50 VA, having properties superior for automated mass production.

Another object of the present invention is to provide toroidal transformers characterised by low production costs, lower no-load losses, higher efficiency, low weight and little volume, making them especially suitable for use in electrical equipment, such as adaptors.

According to a first aspect of the present invention, it relates to a method for manufacture of toroidal transformers, the method comprising the steps of arranging a coil around the periphery of at least one hollow bobbin of elongated shape and of flexible material; bending said at least one bobbin, together with said coil, so that the bobbin ends are brought towards each other, one of said bobbin ends defining an opening; and feeding a ribbon of magnetic material through said opening, so that said ribbon is being wound a required amount of tightly packed winding turns inside said bobbin until essentially the whole interior cavity of said bobbin is filled, said ribbon thereby forming a core.

The present invention solves problems in the prior art associated with winding the coil on a continuous toroidal core using conventional winding machines. Conventionally, there are two different winding processes in the prior art. Firstly, and most commonly, the coil is repeatedly threaded through the empty center hole in the transformer. Secondly, there is a method using a slave roller as shown, for example, in U.S. Pat. No. 4,771,957. In the present invention this slave roller is replaced by a process in which the coil is first wound on a periphery of a straight bobbin. This approach significantly simplifies and speeds up the winding of the coil as compared to both methods known in the prior art.

Further, the process according to the present invention, in which the coil is wound on a periphery of a straight bobbin, allows for the whole coil to be wound in one single fast operation, while this is not the case for the solution presented in U.S. Pat. 4,779,812, in which the wedge-shaped segments commonly only allow between 30 to 50 percent of the total length of voltage coil to be wound from a continuous wire, which lowers the efficiency of the transformer.

Furthermore, the present invention makes it possible to decrease the relative size of the empty center hole of the transformer, since this hole, in principle, is not needed to enable the winding process when using the method according to the present invention. The reduced size of the center hole leads to a shorter magnetic path length (MPL), which means that fewer coil windings need to be wound and that it is easier to reach a higher flow. This also makes it possible to reduce the relative size of the whole transformer, making it even more suitable to use in various electronic equipment.

According to a preferred embodiment of the method according to the present invention, it comprises the additional step of cutting said ribbon at a desired length after having fed said ribbon through said opening. The step of cutting the ribbon after having fed said ribbon through said opening brings about the particular advantage that one need not, necessarily, to pre-cut the ribbon before starting the feeding step, which means significant time savings as compared to the case where one needs to pre-cut the ribbon in matched lengths in advance. Rather, according to the present invention, it is possible to perform the feeding step using ribbon rolls directly as they come from the supplier. This means that the present method is cheaper, simpler and more suitable for mass production.

According to another preferred embodiment of the method, it comprises the additional step of pre-bending said ribbon at the end intended to first be fed through said opening. The step of pre-bending the ribbon contributes to make the ribbon strive towards the center of the bobbin (i.e. the inner curvature of the cavity). In other words, the pre-bending step reduces slack and makes it easier for the ribbon to be wound inside the bobbin, thus lowering the risk for the ribbon to break or get stuck because of jamming or too high friction or similar reasons.

According to another preferred embodiment of the method, it comprises the additional step of providing a part of said ribbon first being fed into the bobbin essentially corresponding to the first wound winding inside said bobbin of said ribbon, on the side facing the inner curvature of the interior hollow cavity of the bobbin, with a layer having a low coefficient of friction for facilitating sliding of said ribbon while being wound inside said bobbin. This low-friction layer primarily acts to reduce the obstacles related to stoppage or jamming of the ribbon that are often experienced when winding ribbons according to the prior art.

Still further, said layer is preferably provided by at least one of an adhesive tape having a first side with low coefficient of friction and a second side being adhesive, a coating with low coefficient of friction, and a fluid. All these surfaces are easily applicable and as such especially suitable for automated mass-production.

According to another preferred embodiment of the method, it comprises the additional step of arranging a flexible transmission element so that it is in continuous co-operation with the innermost winding of said ribbon, further facilitating sliding of said ribbon while being wound inside said bobbin, thus forming the core. The flexible transmission element acts to improve the filling degree of the ribbon inside the bobbin, either through transmitting a pulling force or a pushing force, or both. Further, said flexible transmission element is preferably comprised of at least one of a thread, a wire, a chain, an adhesive tape, a belt, a magnetic force, a roll device, and a meshing device. In any case, said flexible transmission element is reusable and easy to arrange, so that said flexible transmission element suitable for automated mass production.

According to another preferred embodiment of the method, it comprises the additional step of arranging mediating means in connection to said ribbon for mediating co-operation between said flexible transmission element and said ribbon, said mediating means engaging with said flexible transmission element over a distance corresponding to at least a fraction of the innermost winding inside said bobbin of said ribbon.

Said mediating means is preferably comprised of at least one of an adhesive tape, an adhesive coating, a glue, a groove, and a meshing device. The mediating means is adapted to engage with both the ribbon and the flexible transmission element so that the movement of the flexible transmission element is transmitted to the ribbon so that it may more easily be wound inside the bobbin. The mediating means is so constituted that it handles large forces of friction.

In a preferred embodiment said mediating means comprises a from said ribbon protruding part of said layer. This refers, in one embodiment of the present invention, to the case where said layer is provided by an adhesive tape being fixed to the part of the ribbon intended to first be fed through the opening into the bobbin. Said tape is fixed so that a part of the adhesive side of the tape protrudes outside of the ribbon, free to engage with the flexible transmission element, which in this case preferably could comprise a thread or wire.

According to another preferred embodiment of the method, the step of feeding said ribbon of magnetic material through said opening further comprises rotating said bent bobbin together with said coil, and stopping, essentially instantaneously, the rotation of said bent bobbin together with said coil. A main advantage of this operation is the utilization of the principles for moment of inertia, by the effect of which the ribbon is forced to penetrate the opening into the bobbin and wind itself inside said bobbin in a single operation in a way that is easy to adapt for mass production purposes.

According to another preferred embodiment of the method, the step of feeding said ribbon of magnetic material through said opening further comprises injecting a medium through said opening, thereby creating a variable gap between the outer curvature of the interior of said hollow bobbin, being in a bent position, and said ribbon; and leading said medium out from said hollow bobbin.

Said medium should primarily act to lower the forces of friction between the outer curvature of the interior cavity of the hollow bobbin and the ribbon when the latter is being wound inside the bobbin. In addition said medium has the advantage of helping to push the ribbon further inward, by help of compressive forces exerted onto the ribbon by the movement of the injected medium. Said medium is preferably comprised of at least one of a gas and a fluid. However, possibly, the medium could be a solid as well, such as a powder.

Further, in a preferred embodiment, said method for manufacture of toroidal transformers according to the present invention is performed in a magnetic field. Said magnetic field is preferably a variable magnetic field and presents two main advantages as compared to the prior art. Firstly, the magnetic field provides the windings of the ribbon with adhesive properties so that the windings stick to each other while the ribbon is being wound inside the bobbin. This contributes to a tightly formed core, having preferred electromagnetic features. Secondly, the magnetic field can cause a turning force onto said ribbon, further facilitating the forming of the core. This may especially be the case if the magnetic field is provided with alternate strength in different sections along the bent bobbin and then rotating the toroid around the main axis.

According to another aspect of the present invention, it relates to a bobbin for manufacture of toroidal transformers, essentially comprising an elongated tube, characterised by said elongated tube being made by a flexible material and adapted to be bent, so that the ends of said elongated tube may be brought towards each other, one of said ends of said elongated tube defining an opening; and said elongated tube having an essentially rectangular interior hollow cross-section.

The main advantage of the bobbin is that it allows for the winding of the coil to be performed using conventional winding machines. This is because said winding can be performed along a straight stretch, the bobbin being in a straight position, while traditionally, toroidal transformers are manufactured so that the winding of the coil is performed around a donut-shaped core, the disadvantages of which have been described earlier. Another advantage of the bobbin according to the present invention is that it provides insulation sufficient to withstand voltage stresses between the core and the coil windings in the toroidal transformer, since it remains as part of the finally assembled toroidal transformer manufactured according to the method of the present invention.

Furthermore, the bobbin is of a flexible material and adapted to be bent so that the bobbin ends can be brought towards each other. The flexible material could for example be plastic material or rubber allowing the bobbin to be made in one piece by plastic moulding or similar methods. In one embodiment, said flexible material is a low-friction material. This especially an advantage for the interior cavity of the bobbin, making it easier to wind the ribbon inside the bobbin. Alternatively, the bobbin may be coated with a low-friction coating inside the hollow cavity.

The interior hollow cross-section of the bobbin is essentially of rectangular shape in order for the bobbin to be able to receive and accommodate the core material, as this core material comes in the form of a ribbon having a flattened rectangular-shaped cross-section, so that said ribbon, when being tightly wound inside the bobbin, builds up a core with an essentially rectangular-shaped cross-section.

According to another aspect of the present invention, it relates to a system for manufacture of toroidal transformers, the system comprising means for performing said method for manufacture of toroidal transformers. The advantages obtained with said system correspond to those of said method for manufacture of toroidal transformers according to the present invention and of said bobbin for manufacture of toroidal transformers according to the present invention, previously discussed.

According to another aspect of the present invention, it relates to a toroidal transformer manufactured by the above method. Such a toroidal transformer may be used in electrical equipment, such as adaptors.

### BRIEF DESCRIPTION OF THE DRAWINGS

The features of the present invention will be more apparent upon reference to the drawings, wherein:

FIG. 1 is a perspective drawing showing a bobbin according to one embodiment of the present invention to be used for manufacturing of toroidal transformers;

FIG. 2 is a perspective drawing, including a partial enlargement, showing one embodiment of a bobbin according to the present invention, where the bobbin ends are equipped with joining means;

FIG. 3 is a perspective drawing, with a partial cut-away, showing another embodiment of the bobbin according to the present invention, comprising a slot set;

FIG. 4 is a perspective drawing showing the bobbin in FIG. 1, with a coil wound around the bobbin;

FIG. 5 is a perspective drawing showing said bobbin being bent, together with said coil, so that the bobbin ends are brought towards each other, one of said bobbin ends defining an opening;

FIG. 6 is a perspective drawing of the bent bobbin in FIG. 3, showing a ribbon of magnetic material being fed through said opening, thereby forming a core, and a flexible transmission element arranged so that said flexible transmission element co-operates with said ribbon, further facilitating the forming of said core;

FIG. 7 is a flow chart corresponding to one embodiment of the method for manufacture of toroidal transformers according to the present invention;

FIG. 8 is a schematic illustration of the method according to one embodiment of the present invention being performed in a magnetic field;

FIG. 9 shows, from the left to the right, the process of rotating and stopping the transformer according to one embodiment of the present invention, and

FIG. 10 is a perspective drawing showing a ribbon of magnetic material being fed into a bobbin (shown transparent) and a flexible transmission element arranged so that it co-operates with said ribbon via mediating means.

FIG. 11 is a schematic illustration of the principles for a roll device arranged outside the bobbin for performing the pre-bending operation.

### DETAILED DESCRIPTION OF PREFERRED EMBODIMENTS OF THE INVENTION

The invention will now, by way of example and for purposes of illustration only, be described further, with reference to the drawings.

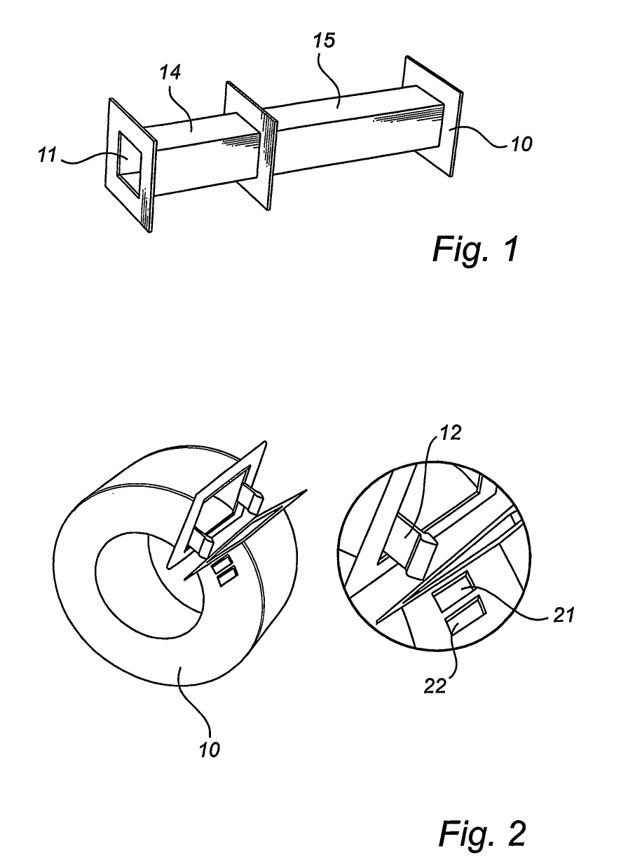

FIG. 1 is a perspective drawing showing one embodiment of a bobbin 10 according to the present invention to be used for manufacturing of toroidal transformers.

The bobbin 10 is essentially comprised of an elongated tube of flexible material. Said flexible material could for example be plastic material or rubber, which besides making the bobbin 10 adapted to be bent so that the ends of said elongated tube may be brought towards each other, also provides the additional advantage of insulation sufficient to withstand voltage stresses between the core and the coil windings in the toroidal transformer, since bobbin 10 remains a part of the finally assembled toroidal transformer manufactured according to the method of the present invention. Said flexible material further allows the bobbin to be made in one piece by plastic moulding or similar methods. In one embodiment said flexible material is a low-friction material. Especially, in the interior cavity of the bobbin 10, this low-friction material makes it easier to wind the ribbon inside the bobbin 10. Alternatively, the bobbin 10 may be coated with a low-friction coating inside the hollow cavity.

The interior hollow cross-section 11 of bobbin 10 is essentially of rectangular shape in order for the bobbin 10 to be able to receive and accommodate the core material, as this core material comes in the form of a ribbon having a flattened rectangular-shaped cross-section, so that said ribbon, when being tightly wound inside the bobbin, builds up a core with an essentially rectangular-shaped cross-section.

Further, FIG. 1 shows an embodiment of the bobbin 10 comprising a first section 14 for a primary winding and a second section 15 for a secondary winding. In another embodiment, however, the bobbin 10 consists of only one section for which the primary and secondary windings are wound one on top of one another, both alongside the whole elongated bobbin. Hence, in this case there is no dividing part in the middle of the bobbin 10. In all cases, the winding takes place before the bobbin is bent.

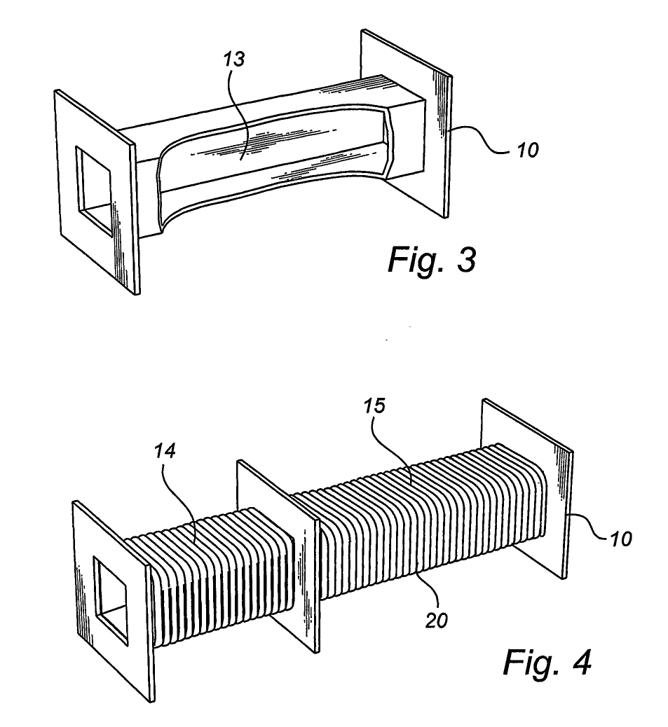

FIG. 2 is a perspective drawing, including a partial enlargement, showing one embodiment of a bobbin 10 according to the present invention to be used for manufacturing of toroidal transformers, where, as a specific feature, the bobbin ends are preferably equipped with joining means 12 adapted for joining the ends together in one, single operation, thus securing the fastening of the bobbin ends to one another. This allows for forming and ensuring a toroidal shape after the coil has been wound around the bobbin 10. These joining means 12 could, for example, comprise a clip device that is preformed during plastic moulding of the bobbin and thereby part of the bobbin itself, as in FIG. 2, or include the addition of an adhesive coating. The hole 21 is used during the feeding step, leaving a spacing between the bobbin ends through which the ribbon may be fed, and the hole 22 is used for completely closing the toroidal ring, when the interior of the bobbin is filled satisfactory.

FIG. 3 is a perspective drawing, with a partial cut-away, showing another embodiment of the bobbin 10 according to the present invention, comprising a slot set 13 comprising at least one slot, being arranged inside said bobbin for guiding said flexible transmission element 50, said slot set 13 being helically arranged alongside the outer curvature of the interior of said hollow bobbin being in a bent position. The slot set 13 is adapted to receive the flexible transmission element and bring it in position before it is tightened and brought towards the mediating means. The slot set 13 thus makes the application of the flexible transmission element easier.

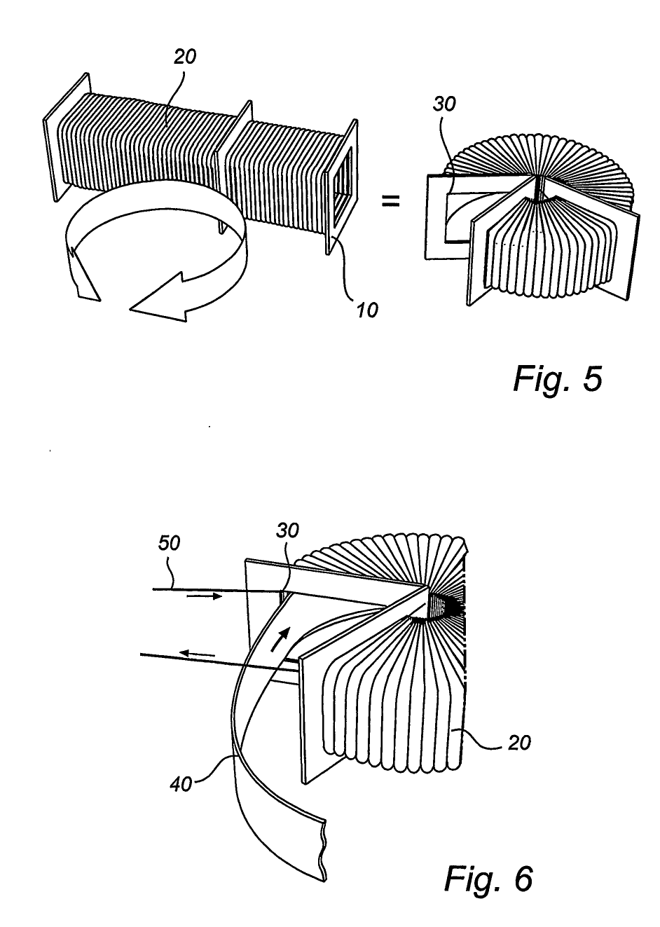

FIG. 4 is a perspective drawing showing the bobbin in FIG. 1, with a coil 20 arranged around the bobbin, corresponding to the first main step S10 of the method according to the present invention. In FIG. 4, the coil 20 comprises a primary winding wound around a first section 14 and a secondary winding wound around a second section 15. Most advantageously, the winding of the coil is performed by conventional winding machines in an automated operation.

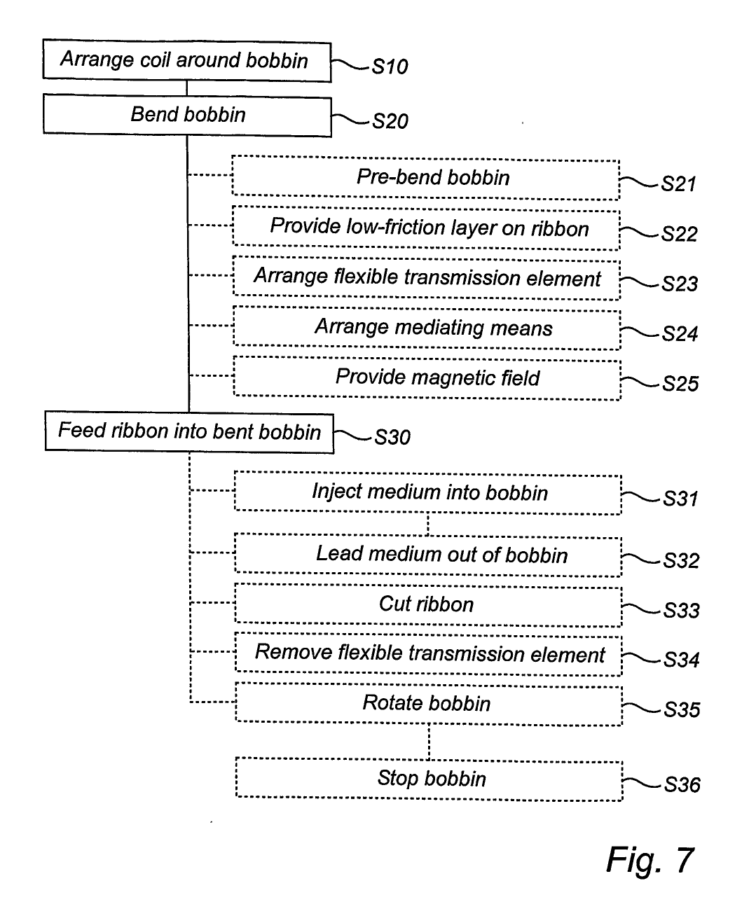

FIG. 5 is a perspective drawing showing said bobbin 10 in FIG. 2 being bent, together with said coil 20, corresponding to the second main step S20 in FIG. 7. To the left the bobbin 10 is shown just before it is being bent and to the right the bobbin 10 is shown as it is configured when being bent, the bobbin ends being brought towards each other, one of said bobbin ends defining an opening 30.

FIG. 6 is a perspective drawing of the bent bobbin 10 in FIG. 3 with a coil winding 20, corresponding to the third main step S30 in FIG. 7, showing a ribbon 40 of magnetic material being fed through said opening 30, so that said ribbon 40 is being wound a required amount of tightly packed winding turns inside said bobbin 10 until essentially the whole interior cavity of said bobbin 10 is filled, said ribbon 40 thereby forming a core.

FIG. 6 also shows a flexible transmission element 50 arranged so that said flexible transmission element 50 co-operates with said ribbon 40, further facilitating the forming of said core, while being wound inside said bobbin.

As stated above, the flexible transmission element 50 acts to improve the filling degree of the ribbon 40 inside the bobbin 10, either through transmitting a pulling force or a pushing force, or both. Preferably, said flexible transmission element 50 is in continuous co-operation with the innermost ribbon winding of the core during the whole feeding step. This means that said flexible transmission element 50 does not need to adjust for the increased core diameter as it is being wound inside the bobbin, meaning a simpler process as compared to, for example, U.S. Pat. No. 4,779,812, in which the so called belt means are arranged to engage with the outermost core winding all the time during the winding process.

Further, said flexible transmission element 50 most preferably comprises a thread or a wire. However, in other embodiments, the flexible transmission element 50 is comprised of at least one of a chain, an adhesive tape, a belt, a magnetic force, a roll device, and a meshing device. In any case, said flexible transmission element is reusable and easy to arrange, so that said flexible transmission element suitable for automated mass production.

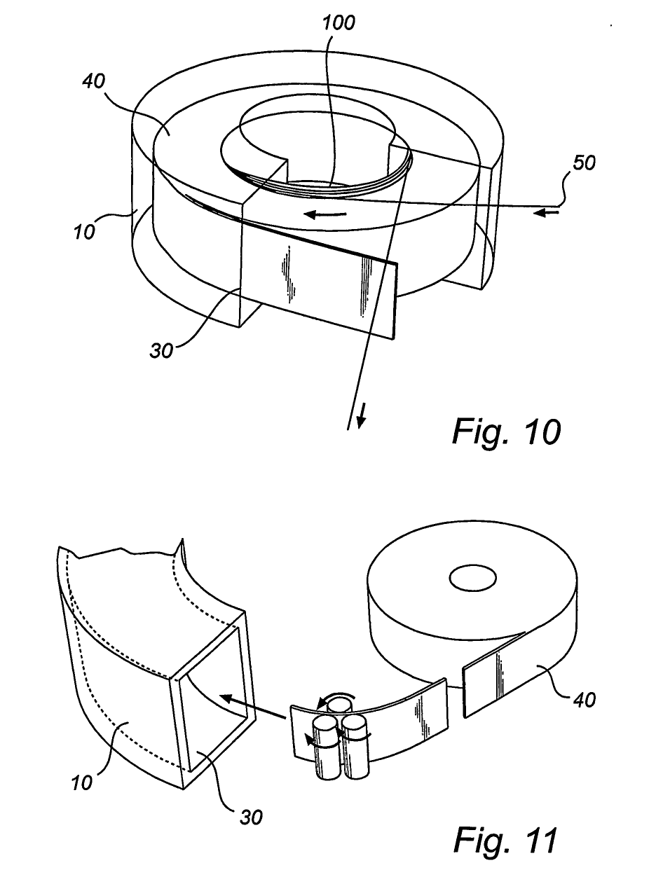

The arrangement of the flexible transmission element is also shown in FIG. 10, which is further described in connection to the description of step S24 below.

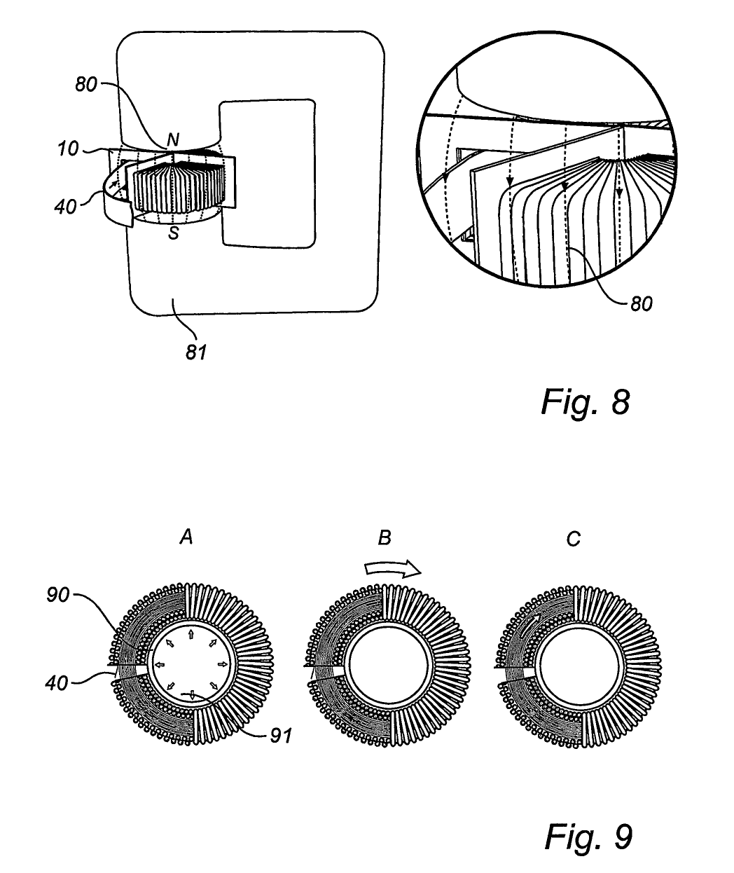

FIG. 7 is a flow chart corresponding to one specific embodiment of the method for manufacture of toroidal transformers according to the present invention. In the description below the numbered references, i.e. other than those representing the steps of the method, refer to the same numbered references as in the previous figures, FIGS. 1 to 6 and in the subsequent FIGS. 8 to 10.

In step S10, a coil 20 is arranged around the periphery of a hollow bobbin 10 of elongated shape and of flexible material. The coil 20 is arranged in place by the use of a conventional winding machine.

Thereafter, in step S20, the bobbin 10 is bent together with the coil 20 that is wound around it, so that the bobbin ends are brought towards each other and one of said bobbin ends defines an opening 30, through which the core material can be fed.

In a preferred embodiment of the present invention, the bending step is performed by means of an arrangement or system comprising a plurality of bars or tubes, having a first straight section and a second essentially circular shaped section, onto which the bobbin 10 are thread, said bars or tubes being adapted to convey different temperatures to the bobbin 10, such that when the bobbin is threaded onto the first straight section of said bar or tube it is heated up, making it more adapted for bending as it is advanced onto the second circular-shaped section. When having been shaped into a toroidal form, by being fully threaded onto the second circular-shaped section, the bobbin 10 is cooled down, thus contributing to form and preserve a toroidal shape of the bobbin. After the cooling of the bobbin 10, it may be removed from the bar or tube arrangement and transferred to the next step in the process.

The next main operation of the method, performed in step S30, is to feed a ribbon 40 of magnetic material through said opening 30, so that said ribbon 40 is being wound a required amount of tightly packed winding turns inside said bobbin 10 until essentially the whole interior cavity of said bobbin 10 is filled, said ribbon 40 thereby forming a core.

However, in the particular embodiment of the present invention outlined in FIG. 7, in connection to the feeding step S30 there is also performed a number of additional steps, S21 to S25, all of them in various ways preparing for and facilitating the feeding of the ribbon 40 into the bobbin 10 and being discussed in more detail below. Further, as will be clarified in more detail later, steps S31 to 36 also contribute in various ways to facilitating the feeding of the ribbon 40 into the bobbin 10.

So, in step S21, after the bobbin 10 has been bent together with the coil 20 around it, the ribbon 40 is first pre-bent at the end of it intended to first be fed through opening 30.

The pre-bending operation is preferably performed by a roll device, arranged outside opening 30, for which the principles are illustrated in FIG. 11. Said roll device also serves as a pushing device, pushing ribbon 40 towards and through opening 30 into the bobbin 10, further facilitating the winding of the core material inside the bobbin. Due to the pre-bending operation the ribbon is better adapted for striving towards the center of the bobbin (i.e. the inner curvature of the cavity), while being wound. In other words, the pre-bending step reduces slack and makes it easier for the ribbon to be wound inside the bobbin, thus lowering the risk for the ribbon to break or get stuck because of jamming or too high friction or similar reasons.

Thereafter, in step S22, the particular part of said ribbon 40 that is first being fed into the bobbin 10, where said part essentially corresponds to the first wound winding inside said bobbin 10 of said ribbon 40 on the side of said ribbon 40 that faces the inner curvature of the interior hollow cavity of the bobbin 10, is provided with a layer having a low coefficient of friction in order to facilitate the sliding of said ribbon 40 when it is wound inside said bobbin.

By this, obstacles related to stoppage or jamming of the ribbon 40 that otherwise could be are reduced. Furthermore, the layer contributes to transform a torsional force into a gripping force, which leads to that it is no longer necessary to apply a welding joint to the ribbon in order to fix the innermost winding of the ribbon, as in, for example, U.S. Pat. No. 4,779,812, which, by the way, would not be appropriate or even possible with the method according to the present invention, because of the closed structural configuration of the bent bobbin with the coil wound around it.

Further, said part of said ribbon first being fed into the bobbin preferably corresponds essentially to the first wound winding inside said bobbin of said ribbon. It is essentially the innermost winding of the ribbon that directly and actively is in close contact with the bobbin. To apply said low-friction surface to additional windings could in fact counteract the continuous tightening of the windings inside the bobbin, so that there is a risk for jamming of the ribbon or that the ribbon is not wound tight enough.

Still further, in the most preferred embodiment said layer is provided by an adhesive tape having a first side with low coefficient of friction and a second side being adhesive. In other embodiments, however, said layer could comprise at least one of a coating with low coefficient of friction and a fluid.

In step S23, a flexible transmission element 50 is arranged so that it can be in continuous co-operation with the innermost winding of said ribbon 40, thereby further facilitating the sliding of the ribbon 40 while being wound inside said bobbin 10 and contributing to forming the core.

In step S24, mediating means are arranged in connection to said ribbon 40 for mediating co-operation between said flexible transmission element 50 and said ribbon 40, as was shown in FIG. 6, said mediating means engaging with said flexible transmission element 50 over a distance corresponding to at least a fraction of the innermost winding inside said bobbin 10 of said ribbon 40. The mediating means is adapted to engage with both the ribbon 40 and the flexible transmission element 50 so that the movement of the flexible transmission element 50 is transmitted to the ribbon 40 so that it may more easily be wound inside the bobbin 10. The mediating means is so constituted that it can handle large forces of friction.

In the most preferred embodiment of the present invention, shown in FIG. 10, said mediating means 100 comprises a from said ribbon 40 protruding part of said layer provided in step 22. This refers especially to the case where said layer is provided by an adhesive tape being fixed to the part of the ribbon 40 intended to first be fed through the opening 30 into the bobbin 10. Said tape is fixed so that a part of the adhesive side of the tape protrudes outside of the ribbon 40, free to engage with the flexible transmission element 50, which in this case preferably could comprise a thread or wire. Hence, said mediating means 100 most preferably comprises the adhesive side of an adhesive tape. However, other embodiments includes mediating means consisting of at least one of an adhesive coating, a glue, a groove, and a meshing device.

In the particular embodiment shown in FIG. 7, the method is being performed in a magnetic field, which is provided in S25. The magnetic field, also shown in FIG. 8, is preferably a variable magnetic field, provided by a device 81 for producing magnetic fields and the presence of which presents at least two main advantages as compared to the prior art. Firstly, the magnetic field 80 provides the windings of the ribbon 40 with adhesive properties so that the windings stick to each other while the ribbon is being wound inside the bobbin. This contributes to a tightly formed core, having preferred electromagnetic features. Secondly, the magnetic field 80 causes a turning force onto said ribbon, further facilitating the forming of the core. This may especially be the case if the magnetic field is provided with alternate strength in different sections along the bent bobbin 10 and then rotating the toroid around the main axis.

Returning again to FIG. 7, in step S31, a medium is injected through said opening 30, so that a variable gap is created between the outer curvature of the interior of said bent bobbin 10, and said ribbon 40.

In step S32, the medium injected in step S31 is lead out from the bobbin 10. In fact, steps S31 and S32 are performed in parallel and more or less continuously during the whole feeding step. Said medium act to lower the forces of friction between the outer curvature of the interior cavity of the hollow bobbin 10 and the ribbon 40 when the latter is being wound inside the bobbin 10. In addition, said medium has the advantage of helping to push the ribbon 40 further inward, by help of compressive forces exerted onto the ribbon 40 by the movement of the injected medium. Said medium is preferably comprised of at least one of a gas and a fluid. However, possibly, the medium could be a solid as well, such as a powder.

In step S33, the ribbon 40 is cut at a desired length after having been fed through opening 30 into the bobbin 10, so that a core has been formed.

In step 34, the flexible transmission element 50 that was arranged in step S23, is removed.

In step 35, the bent bobbin 10, together with the coil 20, is arranged on a rotation device and rotated at high speed. Thereafter, suddenly, in step S36, the rotation of said bent bobbin 10 together with said coil 20, is stopped, essentially instantaneously. Since these operations (i.e. steps S35 and S36) are being performed in an uninterrupted sequence, one can profit from the principles for moment of inertia, by the effect of which the ribbon 40 is forced to penetrate the opening 30 into the bobbin 10 and wind itself inside said bobbin 10 in a single operation in a way that is easy to adapt for mass production purposes.

Preferably, the rotation and stopping steps are being performed after the step of cutting the ribbon 40 at a desired length after having fed the ribbon 40 through the opening 30, so that the part of the ribbon 40 still remaining outside of the bobbin 10 can be brought inside the bobbin 10. This allows for the bobbin 10 to be completely filled with the core material without leaving unused space inside the bobbin 10, something that would lower the efficiency of the toroidal transformer. Furthermore, if a part of the ribbon 40 would protrude from the opening of the bobbin outside of the coil windings, the performance of the transformer would be unsatisfactory and insulating reqirements would risk not to be met.

In this embodiment, said rotation device comprises a holder onto which the bobbin 10 is arranged. Said holder could, for example, essentially consist of a grommet, which can be gradually filled with a medium, such as pressurised air, for fixing the bobbin 10 (and emptied of the same, for releasing the bobbin 10 from the holder). Said holder is adapted to rotate at high speed and to be stopped essentially instantaneously on command thereof.

This procedure is also illustrated in FIG. 9, in which is shown in a perspective from above with partial cross-section, from the left to the right, a state A in which a transformer that is being manufactured is arranged on a holder 90 and filled with a pressurized medium 91, a state B in which said transformer is being rotated, and a state C in which said transformer has been stopped instantaneously, so that the ribbon 40 is completely wound in place inside the bobbin, thus forming the core using the principles for moment of inertia.

It should be pointed out that the present invention is not limited to the realizations described above. The foregoing discussion merely describes exemplary embodiments of the present invention. The skilled man will readily recognize that various changes and modifications may be made without departing from the spirit of the invention, as defined in the claims.

For example, not all of the steps described above, except for the three main steps S10, S20 and S30, need to be performed in order for considering the method to be performed according to the present invention. Any of the other steps can, wholly or partly, be left out or modified. Further, the steps need not to be performed according to the above chronology, rather they can be performed in various combinations after each other.

Furthermore, the bobbin can comprise at least two separately manufactured pieces, intended to jointly form the complete bobbin 10. As an example, one of the at least one pieces could hold the primary winding and another of the at least two pieces could hold the secondary winding. The at least two bobbin pieces could be joined together by means similar to the joining means shown in more detail in FIG. 2, either before or after the winding operation. Also in this case the winding takes place around straight bobbin pieces, joined or not.

Another example of a possible modification is that the winding of the coil around the bobbin, besides being performed by conventional winding machines, also may be performed by hand power.

1. Method for manufacture of toroidal transformers, the method comprising the steps of:
arranging a coil around the periphery of at least one hollow bobbin of elongated shape and of flexible material;
bending said at least one bobbin, together with said coil, so that the bobbin ends are brought towards each other, one of said bobbin ends defining an opening; and
feeding a ribbon of magnetic material through said opening, so that said ribbon is being wound a required amount of tightly packed winding turns inside said bobbin until essentially the whole interior cavity of said bobbin is filled, said ribbon thereby forming a core.

2. Method according to claim 1, comprising the additional step of:
cutting said ribbon at a desired length after having fed said ribbon through said opening.

3. Method according to claim 1, comprising the additional step of:
pre-bending said ribbon at the end intended to first be fed through said opening.

4. Method according to claim 1, comprising the additional step of:
providing a part of said ribbon first being fed into the bobbin essentially corresponding to the first wound winding inside said bobbin of said ribbon, on the side facing the inner curvature of the interior hollow cavity of the bobbin, with a layer having a low coefficient of friction for facilitating sliding of said ribbon while being wound inside said bobbin.

5. Method according to claim 4, wherein said layer is provided by at least one of an adhesive tape having a first side with low coefficient of friction and a second side being adhesive, a coating with low coefficient of friction, and a fluid.

6. Method according to claim 1, comprising the additional step of:
arranging a flexible transmission element so that it continuous co-operation with the innermost winding of said ribbon, further facilitating sliding of said ribbon while being wound inside said bobbin, thus forming the core.

7. Method according to claim 5, comprising the additional step of:
arranging mediating means in connection to said ribbon for mediating co-operation between said flexible transmission element and said ribbon, said mediating means engaging with said flexible transmission element over a distance corresponding to at least a fraction of the innermost winding inside said bobbin of said ribbon.

8. Method according to claim 7, wherein said mediating means comprises a from said ribbon protruding part of said layer.

9. Method according to claim 1, wherein the step of feeding said ribbon of magnetic material through said opening further comprises:
rotating said bent bobbin together with said coil; and stopping, essentially instantaneously, the rotation of said bent bobbin together with said coil.

10. Method according to claim 1, wherein the step of feeding said ribbon of magnetic material through said opening further comprises:
injecting a medium through said opening, thereby creating a variable gap between the outer curvature of the interior of said hollow bobbin, being in a bent position, and said ribbon; and
leading said medium out from said hollow bobbin.

11. Method according to claim 1, wherein said method is performed in a magnetic field.

12. Bobbin for manufacture of toroidal transformers, essentially comprising an elongated tube, characterised by: said elongated tube being made by a flexible material and adapted to be bent, so that the ends of said elongated tube may be brought towards each other, one of said ends of said elongated tube defining an opening; and
said elongated tube having an essentially rectangular interior hollow cross-section.

13. System for manufacture of toroidal transformers, the system comprising:
means for arranging a coil around the periphery of at least one hollow bobbin of elongated shape and of flexible material;
means for bending said at least one bobbin, together with said coil, so that the bobbin ends are brought towards each other, one of said bobbin ends defining an opening; and
means for feeding a ribbon of magnetic material through said opening, so that said ribbon is being wound a required amount of tightly packed winding turns inside said bobbin until essentially the whole interior cavity of said bobbin is filled, said ribbon thereby forming a core.

14. Toroidal manufacture of toroidal transformers, according to claim 1.

15. Use of a toroidal transformer according to claim 14 in electrical equipment, such as adaptors.
